(19) United States
(12) Patent Application Publication
(10) Pub. No.: US 2015/0155130 A1
(43) Pub. Date: Jun. 4, 2015

(54) DRAWING APPARATUS, DRAWING METHOD, AND METHOD FOR MANUFACTURING ARTICLE

(71) Applicant: CANON KABUSHIKI KAISHA, Tokyo (JP)

(72) Inventor: Kazuya Kikuchi, Utsunomiya-shi (JP)

(21) Appl. No.: 14/553,834

(22) Filed: Nov. 25, 2014

(30) Foreign Application Priority Data
Nov. 29, 2013 (JP) 2013-247123

(51) Int. Cl. H01J 37/24; H01J 37/244; H01J 37/147; H01J 37/04; H01J 37/317; H01J 37/12

(52) U.S. Cl. CPC H01J 37/243; H01J 37/3177; H01J 37/12; H01J 37/1471; H01J 37/045; H01J 37/244; H01J 2237/31793; H01J 2237/0437

(57) ABSTRACT

An apparatus draws a pattern on a substrate using a plurality of beams. The drawing apparatus includes a control unit configured to control the plurality of beams in units of a plurality of beam groups, a number of the plurality of beam groups being smaller than the number of the plurality of beams, and an instruction unit configured to provide an instruction to the control unit. The instruction unit provides the instruction by adjusting a combination of beam groups to be used for drawing at a certain position on the substrate, based on information about a defective beam among the plurality of beams.

### BACKGROUND OF THE INVENTION

1. Field of the Invention

The present invention relates to a drawing apparatus, a drawing method, and a method for manufacturing an article.

2. Description of the Related Art

With a recent increase in the degree of integration and miniaturization of semiconductor integrated circuits, further miniaturization of a pattern formed on a substrate in an exposure step has been demanded. Also, for a drawing apparatus that draws a pattern on a substrate using a plurality of beams, higher drawing precision has been demanded. However, there is an issue that precise drawing is not realized if the plurality of beams include a beam that is uncontrollable by a control instruction provided from the drawing apparatus (hereinafter referred to as a defective beam).

A drawing apparatus that performs drawing using a plurality of beams (described in Japanese Patent Laid-Open No. 2005-322918) increases the precision of drawing a pattern by performing multilevel control of an irradiation amount on a beam applied to the same position. The drawing apparatus has reserve beams. If there is a defective beam that is unusable for irradiation, a reserve beam is used for drawing instead of the defective beam.

However, the technique described in Japanese Patent Laid-Open No. 2005-322918 does not suggest any measures for a defective beam that is wrongly emitted against an instruction indicating non-irradiation.

### SUMMARY OF THE INVENTION

According to an aspect of the present invention, there is provided an apparatus that draws a pattern on a substrate using a plurality of beams. The apparatus includes a control unit configured to control the plurality of beams in units of a plurality of beam groups, the number of the plurality of beam groups being smaller than the number of the plurality of beams, and an instruction unit configured to provide an instruction to the control unit. The instruction unit provides the instruction by adjusting a combination of beam groups to be used for drawing at a certain position on the substrate, based on information about a defective beam among the plurality of beams.

Further features of the present invention will become apparent from the following description of exemplary embodiments with reference to the attached drawings.

### BRIEF DESCRIPTION OF THE DRAWINGS

FIG. 1 is a diagram illustrating the configuration of a drawing apparatus according to a first embodiment.

FIGS. 2A and 2B are diagrams describing multilevel control of an irradiation amount.

FIG. 3 is a diagram describing a circuit of a control unit for a blanking array.

FIG. 4 is a diagram describing weighting of beams according to the first embodiment.

FIG. 5 is a diagram illustrating the relationship between irradiation levels and serial data according to the first embodiment.

FIG. 6 is a diagram describing the function of a command adjusting unit according to the first embodiment.

FIG. 7 is a diagram describing weighting of beams according to a second embodiment.

### DESCRIPTION OF THE EMBODIMENTS

An embodiment of the present invention is applicable to a drawing apparatus that draws a pattern by irradiating a wafer (substrate) with a plurality of beams (electron beams, ion beams, laser beams, or the like).

Hereinafter, a description will be given of the configuration of a drawing apparatus, a drawing method for a normal case, and a drawing method for a case where a defective beam exists. Here, a defective beam is a beam that is uncontrollable by a control instruction provided by the drawing apparatus.

Examples of a defective beam include a beam that is emitted against an instruction indicating non-irradiation (hereinafter referred to as a white defective beam) and a beam that is not emitted against an instruction indicating irradiation (hereinafter referred to as a black defective beam). Another example is a beam that is emitted with an unacceptable amount of charge relative to an amount of charge specified by an irradiation instruction. The black defective beams may be generated due to clogged apertures of an aperture array 5 or a blanking array 7 (described below). The white defective beams may be generated in a case where a voltage is not normally applied to the blanking array 7, due to disconnection of a wiring line leading to the blanking array 7, for example.

### First Embodiment

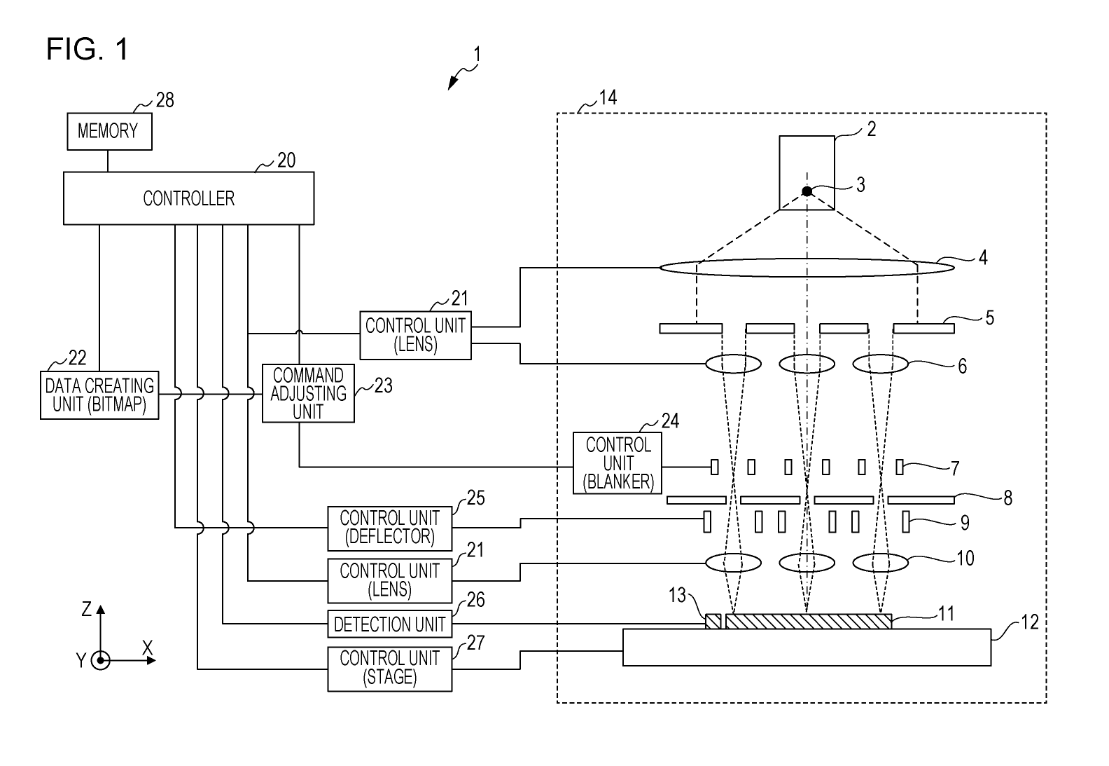

A configuration of a drawing apparatus will be explained. FIG. 1 is a diagram illustrating the configuration of a drawing apparatus 1 according to a first embodiment. In the first embodiment, a description will be given of an example of a drawing apparatus that draws a pattern using a plurality of electron beams.

An electron beam generated by an electron source 2 of the drawing apparatus 1 converges at a crossover 3 and then diverges toward a collimator lens 4. The collimator lens 4 forms the electron beams incident on the collimator lens 4 into a bundle of electron beams parallel to one another. The aperture array 5, which has a plurality of circular apertures arranged two-dimensionally, divides the electron beams that have entered the aperture array 5 substantially vertically into electron beams whose number corresponds to the number of the apertures.

An electrostatic lens 6 is constituted by three electrode plates (illustrated as one set in FIG. 1) having apertures at the positions corresponding to an array of the electron beams that have passed through the aperture array 5. The blanking array 7 is disposed at a position where the electrostatic lens 6 forms an intermediate image of electron beams.

The blanking array 7 includes deflectors (hereinafter referred to as blankers) at the positions corresponding to an array of the electron beams that have passed through the aperture array 5. A voltage to be applied to each blanker of the blanking array 7 is switched using a voltage source (not illustrated), and thereby each electron beam is switched between two levels: irradiation and non-irradiation. In a case where no voltage is applied, the electron beam passes through the blanker, and also passes through a diaphragm 8 having apertures arranged two-dimensionally at the positions corresponding to an array of the electron beams. On the other hand, in a case where a voltage is applied, the track of the electron beam that passes through the blanker is deflected, and the electron beam is shut off by the diaphragm 8.

A deflector 9 performs fine adjustment of irradiation positions by collectively deflecting the electron beams that have passed through the diaphragm 8 to the same direction in a case where a difference occurs between an expected position of a wafer 11 having expected irradiation positions and an actual position of the wafer 11. An electrostatic lens 10 forms an image on the wafer 11 using the electron beams that have passed through the diaphragm 8.

The wafer 11 is placed on a stage 12. The stage 12 is movable in an X-axis direction, a Y-axis direction, and a Z-axis direction. The position of the stage 12 is measured using a moving mirror (not illustrated) on the stage 12 and a laser interferometer (not illustrated). The drawing apparatus 1 draws a pattern while achieving synchronization between the position of the stage 12 and the timing of switching between irradiation and non-irradiation in the individual blankers of the blanking array 7.

A detector 13 is a component that could be used to determine whether or not each electron beam used for irradiation is a defective beam. In the case of measuring the amount of energy of an electron beam using a knife-edge method, a knife-edge-shaped component and a component for detecting transmitted electrons or secondary electrons of an electron beam that has passed the knife-edge-shaped component may be used as the detector 13. Alternatively, a scintillator for converting the energy of an electron beam to light or an optical sensor such as a line sensor may be used as the detector 13.

With a measurement result obtained from the detector 13, information about a defective beam among a plurality of electron beams, which represents the position of the defective beam and the response state of the defective beam, could be detected. The response state of the defective beam is the response state of the electron beam for an irradiation instruction, for example, whether the defective beam is a black defective beam or a white defective beam.

In a case where an irradiation amount of one electron beam is variable in the drawing apparatus 1, the difference between an irradiation amount specified by an instruction and an actual irradiation amount is also one example of a response state. The above-described components of the drawing apparatus 1 and a control unit 24 described below are placed within a vacuum chamber 14. A vacuum pump (not illustrated) evacuates air from the vacuum chamber 14.

A controller 20 includes a central processing unit (CPU), and controls, in a centralized manner, control units 21, a data creating unit 22, a command adjusting unit (instruction unit) 23, a control unit 25, a detection unit 26, a control unit 27, and a memory 28 which are connected to the controller 20. The controller 20 stores data in the memory 28, reads data from the memory 28, and transmits the read data to a component of the drawing apparatus 1.

The controller 20 also includes a circuit (not illustrated) for generating a clock signal, and transmits a clock signal to the command adjusting unit 23, which adjusts a drawing command in view of the response state of a defective beam, or the control unit 27, which controls the stage 12. Further, the controller 20 transmits information representing the position of a defective beam and the response state of the defective beam, read out from the memory 28, to the command adjusting unit 23.

The control units 21, which control the electrostatic lenses 4, 6, and 10, control a voltage to be applied to the electrostatic lenses 4, 6, and 10. There are two control units 21 in FIG. 1, but the control units 21 may be integrated into a single control unit 21.

The data creating unit 22 creates drawing data by converting design data, which is a pattern designed by a user, to bitmap data. At this time, the data creating unit 22 performs a correction process, such as proximity effect correction using an electron beam, to create the drawing data. An irradiation amount in each unit region (certain position) on the wafer 11 is determined based on the bitmap data. Of course, a pattern could be drawn more precisely as the number of irradiation levels of an electron beam applied to a unit region increases.

The command adjusting unit 23 obtains the drawing data created by the data creating unit 22, the clock signal, and the information representing the position of a defective beam and the response state of the defective beam read out from the memory 28 by the controller 20.

In a case where there is no defective beam, the command adjusting unit 23 transmits a control command (instruction) for beams to be transmitted to the individual blankers to the control unit 24, which controls the blanking array 7, and also transmits a clock signal to the control unit 24 (beam control unit). Here, a control command for a beam is serial data that is determined based on the drawing data created by the data creating unit 22. On the other hand, in a case where there is a defective beam, the command adjusting unit 23 transmits a control command and a clock signal to the control unit 24. This control command is generated by changing (adjusting) part of a control command that is used when there is no defective beam, so that irradiation could be performed with a target irradiation amount (expected irradiation amount) using the defective beam.

The control unit 24 controls application of a voltage to each blanker of the blanking array 7 by using the data and clock signal received from the command adjusting unit 23. The control unit 24 and the blanking array 7 may be integrally configured on the same IC chip, together with wiring lines connecting the control unit 24 and the blanking array 7. With this configuration, degradation of the waveform of an electric signal could be suppressed as much as possible, and a decrease in drawing precision could be suppressed as much as possible.

The control unit 25 controls a deflection direction, a degree of deflection, and a deflection timing for the deflector 9. The detection unit 26 transmits information representing a response state of an electron beam detected by the detector 13 to the controller 20. The memory 28 stores design data of a circuit pattern or the like designed by a user, drawing data created by the data creating unit 22, and so forth. Further, the memory 28 stores information representing the position of an electron beam that has been determined to be a defective beam by the controller 20 based on information representing the state of the beam transmitted from the detection unit 26, and the response state of the electron beam.

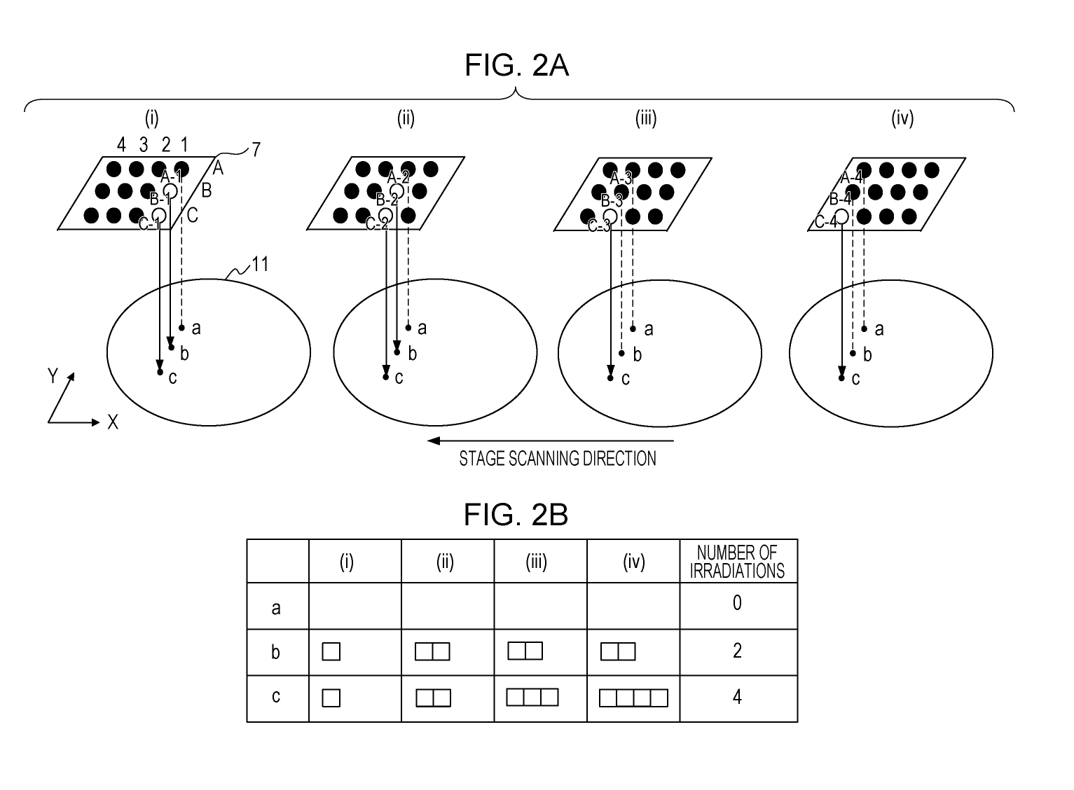

A drawing method will be explained. With reference to FIGS. 2A and 2B, a description will be given of a drawing method for performing drawing with multilevel control of an irradiation amount. States (i), (ii), (iii), and (iv) illustrated in FIG. 2A chronologically show the relationship between positions a, b, and c on the wafer 11 and the blankers used for irradiating the individual positions. The blanking array 7 includes blankers arranged in three rows and four columns.

The rows of the blankers are represented by A to C, and the columns are represented by 1 to 4. The electron beam in row A and column 1 is represented by A-1, for example. Position a is irradiated with electron beams in the individual columns of row A. Position b is irradiated with electron beams in the individual columns of row B. Position c is irradiated with electron beams in the individual columns of row C. A beam that is emitted is represented by a white circle, and a beam that is not emitted is represented by a black circle. It is assumed that the stage 12 is scanned in the direction from the first column toward the fourth column. FIG. 2B illustrates the irradiation amounts at positions a, b, and c after irradiation has finished in individual states (i), (ii), (iii), and (iv) illustrated in FIG. 2A.

State (i) corresponds to a time at which irradiation with electron beams in the first column is performed on positions a, b, and c, where irradiation with electron beams B-1 and C-1 is performed. State (ii) corresponds to a time at which irradiation with electron beams in the second column is performed, where irradiation with electron beams B-2 and C-2 is performed. State (iii) corresponds to a time at which irradiation with electron beams in the third column is performed, where irradiation with only electron beam C-3 is performed. State (iv) corresponds to a time at which irradiation with electron beams in the fourth column is performed, where irradiation with only electron beam C-4 is performed. Thus, the number of irradiations is four at position c, two at position b, and zero at position a.

In this way, each electron beam is controlled with two irradiation levels: irradiation and non-irradiation. Thus, an irradiation amount could be adjusted with five irradiation levels in total (0 to 4) depending on the number of irradiations. Generally, an irradiation amount for a unit region on the wafer 11 could be controlled with the number of irradiation levels calculated by adding one to the number of beams arranged in the scanning direction of the wafer 11.

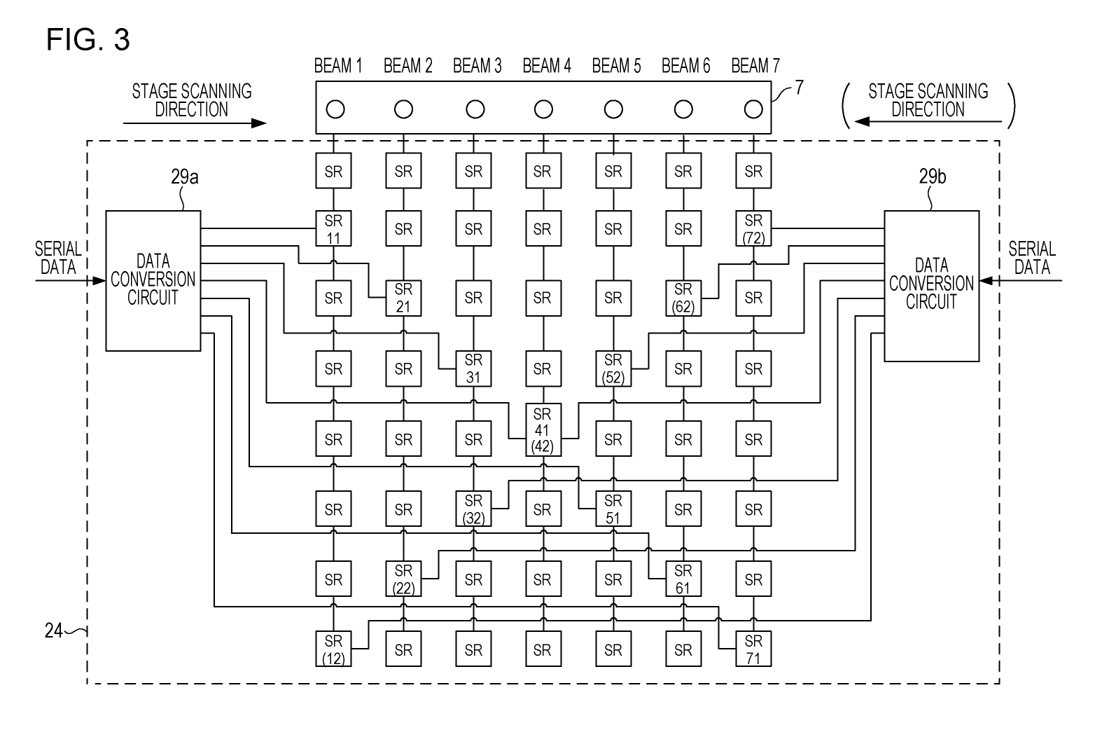

FIG. 3 illustrates an example of the arrangement relationship between a control circuit of the control unit 24 and the blanking array 7. A description will be given of an example in which an irradiation amount is controlled with eight levels by using seven electron beams that pass through certain irradiation positions on the wafer 11.

The control unit 24 includes data conversion circuits 29a and 29b, each of which converts serial data to parallel data. The serial data represents an instruction of irradiation or non-irradiation transmitted from the command adjusting unit 23. The control unit 24 further includes shift registers (SRs) that connect the data conversion circuits 29a and 29b and beams 1 to 7. In a case where the scanning direction of the stage 12 is a right direction when viewed toward the sheet of FIG. 3, an irradiation position first passes a portion just below beam 1, and then passes portions just below beams 2 to 7 in this order. In this case, the command adjusting unit 23 transmits serial data to the data conversion circuit 29a.

Before the serial data is transmitted to the data conversion circuit 29a, a reset signal is input to all the SRs, in order to prevent wrong drawing caused by the data directly connected to the individual beams.

Subsequently, the data conversion circuit 29a stores data representing irradiation or non-irradiation in each of SRs 11 to 71. Every time a clock signal for achieving synchronization between a movement of the stage 12 and an irradiation timing is input to the data conversion circuit 29a, the pieces of data stored in the individual SRs 11 to 71 move one by one to the SRs closer to the beams. When the pieces of data stored in the individual SRs are stored in the SRs closest to the electron beams, the blankers control the electron beams in accordance with the pieces of data.

Before a clock signal is input, data representing a control instruction for the next unit region is stored in the SRs 11 to 71. In this way, the individual SRs receive a clock signal and a control instruction, and thereby the individual unit regions on the wafer 11 are irradiated or not irradiated with the individual electron beams.

In a case where the scanning direction of the stage 12 is the opposite direction, that is, a left direction when viewed toward the sheet of FIG. 3, the data conversion circuit 29b receives serial data. The data conversion circuit 29b stores data representing irradiation or non-irradiation in the SRs 12 to 72.

Alternatively, the data conversion circuit 29b may be omitted, and the data conversion circuit 29a may also function as the data conversion circuit 29b. In a case where the scanning direction of the stage 12 is the left direction when viewed toward the sheet of FIG. 3, a wire connection may be made switchable so that the wire connection to the SR 11 can be switched to the SR 72, the wire connection to the SR 21 can be switched to the SR 62, and the like. Accordingly, the space for placing the data conversion circuit 29b can be reduced.

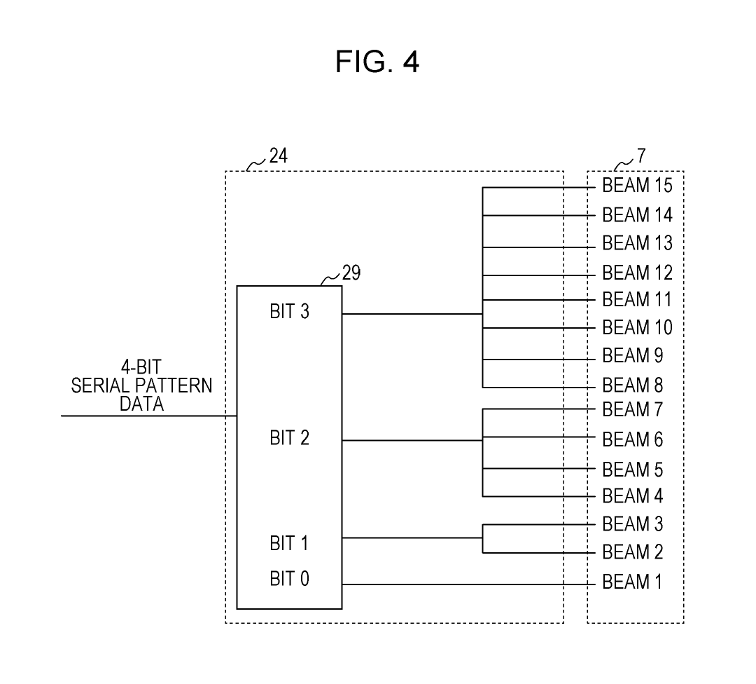

FIG. 4 is a diagram illustrating the connection relationship between the data conversion circuit 29 and electron beams. Here, the illustration of the SRs in FIG. 3 is omitted. In FIG. 3, the number of electron beams is seven, but FIG. 4 illustrates a case where the number of electron beams is fifteen. In this case, an irradiation amount for a unit region could be controlled with sixteen levels, using zero to fifteen electron beams.

However, in a case where the number of electron beams increases and the data input to the data conversion circuit 29 is serial data that corresponds to each electron beam in a one-to-one relationship, an amount of data to be transmitted increases. That is, in a case where the number of electron beams for irradiating a unit region is fifteen, serial data of 15 bits is to be transmitted.

Thus, in this embodiment, wiring lines are configured so as to reduce the number of bits of serial data to be transmitted and to enable multilevel control of an irradiation amount. There are a wiring line of bit 0 for transmitting data to only beam 1, a wiring line of bit 1 for transmitting data to beam 2 and beam 3, a wiring line of bit 2 for transmitting data to beam 4 to beam 7, and a wiring line of bit 3 for transmitting data to beam 8 to beam 15. Wiring lines for transmitting the same data to a plurality of beams are provided. In this way, a beam drawing command is transmitted in the form of data that controls beams in units of beam groups the number of which is smaller than the total number of beams, and thereby the number of bits of data could be reduced to four.

The same data is given to all the beams that belong to the same beam group. For example, in a case where an irradiation command is input to the beam group of bit 3, irradiation commands for beam 8 to beam 15 are stored in the SRs connected to the data conversion circuit 29.

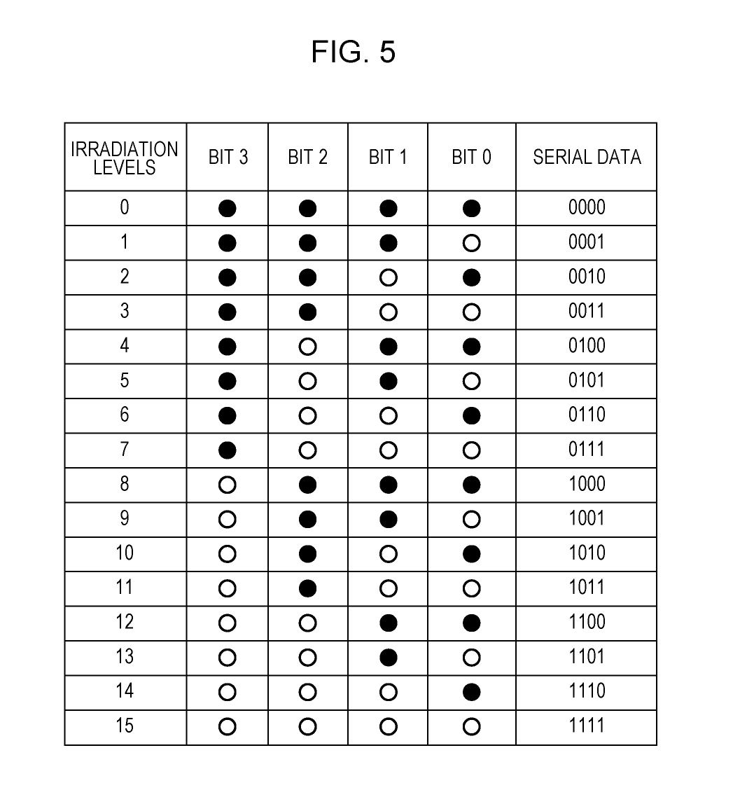

FIG. 5 is a diagram illustrating the relationship between irradiation levels and serial data. A white circle represents irradiation (logical 1), and a black circle represents non-irradiation (logical 0). For example, in the case of irradiating a certain irradiation position at level 7, the command adjusting unit 23 may transmit serial data (0111) to the data conversion circuit 29. In response to the serial data, irradiation with beam 1 to beam 7 is performed. In the case of irradiating a certain irradiation position at level 13, the command adjusting unit 23 may use serial data (1101). In response to the serial data, irradiation with beam 1 and beam 4 to beam 15 is performed.

In this way, weighting is performed so that one of the beam groups and another one of the beam groups have different numbers of beams. With appropriate weighting performed on the number of electron beams belonging to each beam group, the number of bits of serial data to be transmitted could be reduced, and also drawing could be performed by controlling an irradiation amount from zero beams (0000) to fifteen beams (1111).

A drawing method in a case where a defective beam exists will be explained. The above-described configuration of the control unit 24 is a configuration for a case where there is no defective beam, and is a configuration with which a target irradiation amount could be obtained even if a defective beam exists. Hereinafter, the reason will be described.

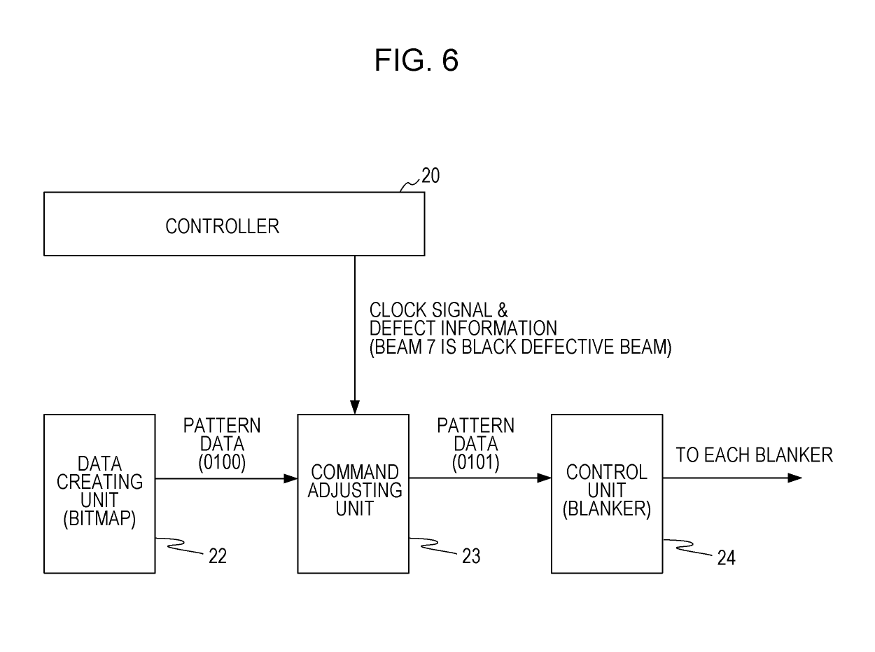

FIG. 6 illustrates the relationship among the controller 20, the data creating unit 22, the command adjusting unit 23, and the control unit 24. Information representing the position of a defective beam detected using the detector 13 and the response state of the beam (black defective beam or white defective beam) is stored in the memory 28, and the controller 20 transmits the information to the command adjusting unit 23 together with a clock signal.

A description will be given of an example in which beam 7 is a black defective beam. The data creating unit 22 transmits drawing data of bitmap display, created using design data, to the command adjusting unit 23. For example, in the case of irradiating a certain irradiation position at level 4, the data creating unit 22 transmits serial data (0100) to the command adjusting unit 23. In a case where the command adjusting unit 23 has not received information about a defective beam from the controller 20, the command adjusting unit 23 transmits the serial data (0100) to the control unit 24 together with a clock signal. In a case where the command adjusting unit 23 has received information about a defective beam, the command adjusting unit 23 adjusts the data to be transmitted to the control unit 24 in view of the response state of the defective beam.

In a case where beam 7 belonging to the beam group of bit 2 is a black defective beam and where serial data (0100) is used, the irradiation amount is level 3, which is smaller than an expected irradiation amount of level 5. Thus, the command adjusting unit 23 changes the serial data to serial data (0101) with which irradiation is performed at level 4 by further using beam 1, and transmits the serial data to the control unit 24. In this way, the command adjusting unit 23 provides an instruction by changing the combination of the beam groups to be used for drawing, using the information indicating that beam 7 is a black defective beam. Accordingly, the drawing apparatus 1 is capable of performing irradiation with a target irradiation amount even if a black defective beam exists.

Also in a case where a white defective beam exists, a target irradiation amount could be obtained in a similar way. For example, in a case where beam 7 is a white defective beam and where irradiation is to be performed at level 11, an actual irradiation amount is level 12. Thus, the command adjusting unit 23 adjusts the serial data (1011) received from the data creating unit 22 to serial data (1010) with which irradiation is performed at level 10, and transmits the serial data to the control unit 24. As a result of changing the instruction for beam 1 corresponding to bit 0 to an instruction indicating non-irradiation, the blanking array 7 is capable of performing irradiation without changing the expected number of irradiations of a unit region with electron beams.

In this way, in a case where the position of a defective beam and the response state of the defective beam are identified, the wafer 11 could be irradiated with a target irradiation amount while using the defective beam, by changing the combination of the beam groups to be used for drawing by the command adjusting unit 23. This is advantageous, compared to the related art, in that measures could be taken even if a white defective beam exists.

In this embodiment, weighting is performed on the number of electron beams belonging to each beam group. Accordingly, multilevel control of an irradiation amount could be performed on a unit region, and also an amount of serial data that represents a control command and that is to be transmitted could be reduced. In a case where the total number of electron beams is larger than that in this embodiment, weighting may be performed so that there are beam groups including the same number of electron beams.

In the case of forming beam groups, a beam group including a single beam may be prepared. Accordingly, a combination of beam groups could be easily adjusted in a case where a target irradiation amount is an odd-numbered level. Further, in case an electron beam belonging to the beam group of bit 0 becomes a defective beam, at least one reserve beam group including one reserve beam may be prepared. In this embodiment, in which a combination of beam groups is adjusted, irradiation could be performed with a target irradiation amount while suppressing an increase in size of the apparatus, compared to the case of preparing reserve beams the number of which is the same as the number of defective beams.

The command adjusting unit 23 may store the data illustrated in FIG. 5 in the memory 28 in the command adjusting unit 23 in advance, and may adjust a command using the data. Alternatively, an adjusting unit for determining an instruction change method may be separately provided (not illustrated). In FIG. 4, beam 1 to beam 15 are arranged in this order, but it is not necessary to perform irradiation in this order. The wiring lines may be appropriately changed so that the beams belonging to the beam groups of bit 0, bit 1, bit 2, and bit 3 are symmetrically arranged from the center in irradiation order.

### Second Embodiment

In a case where the configuration of the control unit 24 and the blankers illustrated in FIG. 4 is used and where an electron beam belonging to the beam group of bit 3 is a defective beam, there are two patterns of a case where a target radiation amount is not obtained. In a case where the defective beam is a black defective beam, it is impossible to perform irradiation with a maximum irradiation amount of level 15. In a case where the defective beam is a white defective beam, it is impossible to perform irradiation with a minimum irradiation amount of level 0. On the other hand, in a case where the configuration of the control unit 24 and the blankers illustrated in FIG. 4 is used and where the beam of bit 0, that is, a single beam 1, is a black defective beam, it is impossible to perform irradiation at an odd-numbered level. In a case where a single beam 1 is a white detective beam, it is impossible to perform irradiation at an even-numbered level.

That is, it is understood that the number of available irradiation levels is larger in a case where a defective beam belongs to the beam group of bit 3 than in a case where a defective beam belongs to the beam group of bit 0. In the case of providing a control command in units of beam groups, irradiation with a target irradiation amount could be performed more easily if a defective beam belongs to a beam group including a larger number of beams, by compensating for an influence of the defective beam.

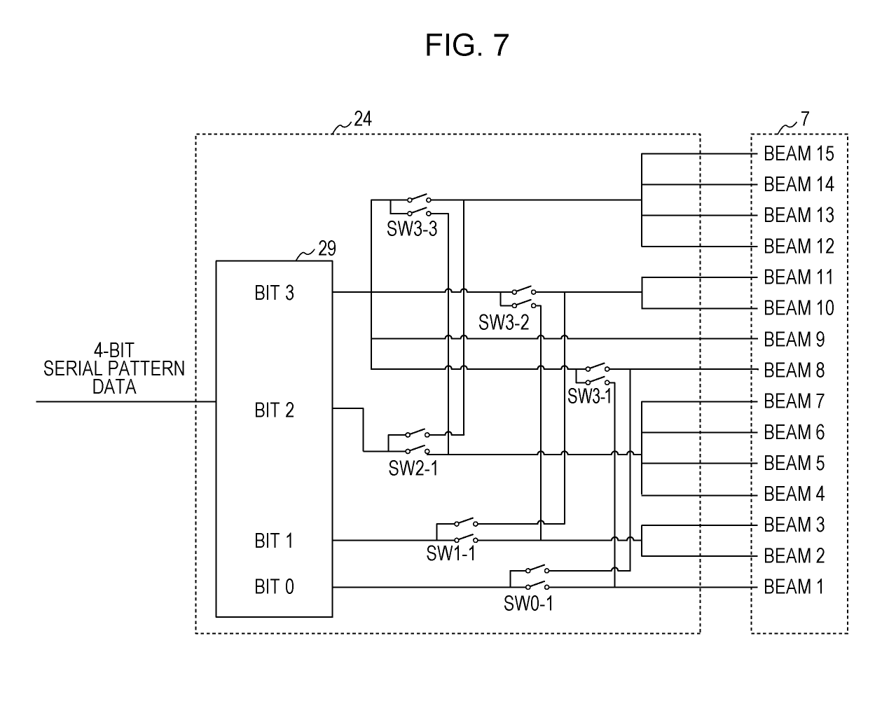

Accordingly, in the second embodiment, a description will be given of an example in which a defective beam could be moved from the beam group to which the defective beam belongs to another beam group including a larger number of beams. FIG. 7 illustrates the relationship between the control unit 24 and the blankers according to the second embodiment. The second embodiment is different from the first embodiment in that connections between the control unit 24 and wiring lines for transmitting control commands of the blanking array 7 could be switched using switches.

The beam group of bit 0 has a switch (SW) 0-1 with which a connection to beam 1 or beam 8 could be established. The beam group of bit 1 has a SW 1-1 with which a connection to beams 2 and 3 or beams 10 and 11 could be established. The beam group of bit 2 has a SW 2-1 with which a connection to beams 4, 5, 6, and 7 or beams 12, 13, 14, and 15 could be established. The beam group of bit 3 has a SW 3-1 with which a connection to beam 1 or beam 8 could be established, a SW 3-2 with which a connection to beams 2 and 3 or beams 10 and 11 could be established, and a SW 3-3 with which a connection to beams 4, 5, 6, and 7 or beams 12, 13, 14, and 15 could be established.

In a case where there is no defective beam, the command adjusting unit 23 causes the control unit 24 to close the lower circuits of the SW 0-1, SW 1-1, and SW2-1 and open the upper circuits thereof, and to close the upper circuits of the SW 3-1, SW 3-2, and SW 3-3 and open the lower circuits thereof. As a result of switching the switches SW in this way, the wiring configuration illustrated in FIG. 4 is realized. This state is regarded as an initial state.

Next, a description will be given of a case where a defective beam exists. For example, in a case where beam 1 is a defective beam, switching is performed to close the upper circuit of the SW 0-1 and open the lower circuit thereof, and to close the lower circuit of the SW 3-1 and open the upper circuit thereof. Accordingly, beam 8 belongs to the beam group of bit 0, and beam 1 belongs to the beam group of bit 3.

In a case where beam 2 or beam 3 is a defective beam, switching is performed to close the upper circuit of the SW 1-1 and open the lower circuit thereof, and to close the lower circuit of the SW 3-2 and open the upper circuit thereof. Accordingly, beam 10 and beam 11 belong to the beam group of bit 1, and beam 2 and beam 3 belong to the beam group of bit 3.

In a case where any one of beams 4, 5, 6, and 7 is a defective beam, switching is performed to close the upper circuit of the SW 2-1 and open the lower circuit thereof, and to close the lower circuit of the SW 3-3 and open the upper circuit thereof. Accordingly, beams 12, 13, 14, and 15 belong to the beam group of bit 2, and beams 4, 5, 6, and 7 belong to the beam group of bit 3. Finally, in a case where any one of beam 8 to beam 15 is a defective beam, the connection state remains the initial state.

The wiring is switched in this manner, so that any defective beam belongs to the beam group of bit 3. Accordingly, the combination of the beam groups to be used for irradiation is adjusted in accordance with the response state of a defective beam as in the first embodiment, and thereby irradiation could be performed with a target irradiation amount in view of a defective beam.

Other embodiments will be explained. The control of irradiation or non-irradiation of each electron beam is not necessarily performed using the blanking array 7 and the diaphragm 8. A device of another form may be used as long as the device is capable of individually controlling an exposure amount of a plurality of electron beams and irradiation or non-irradiation by using drawing data.

Information indicating how to change a combination of electron beam groups in a case where a certain electron beam is a defective beam, or information indicating how to switch the wiring to change a combination of electron beam groups, may be stored in advance in the form of a table. Accordingly, the process of adjusting data transmitted from the data creating unit 22 and providing a control instruction, performed by the command adjusting unit 23, is simplified.

The drawing apparatus 1 may include a plurality of optical systems, each being to form an electron beam and including the electron source 2 to the electrostatic lens 10 which is an objective lens. Further, the drawing data adjusted by the command adjusting unit 23 may be stored in the memory 28 via the controller 20, and the same drawing data may be applied to all wafers in the same lot. Accordingly, the throughput could be increased.

According to the above-described embodiments, the command adjusting unit 23 instructs the control unit 24 so as to change the combination of the beam groups to be used for drawing, based on information about a defective beam. Accordingly, drawing could be performed with a target irradiation amount even if a defective beam exists.

Multilevel control of an irradiation amount for a unit region enables increased drawing precision. Because multilevel control is performed on an irradiation amount, a degree of degradation of drawing precision due to one white defective beam or black defective beam could be suppressed, compared to the case of performing two-level control of an irradiation amount. Further, even if a defective beam exists, drawing is performed using the response state of the defective beam, and accordingly the number of operations for exchanging devices, such as the control unit 24 and the blanking array 7, could be reduced.

The command adjusting unit 23 may perform the above-described process inside the controller 20 if the function thereof is not changed. In a case where weighting of electric charge could be performed for each electron beam, the command adjusting unit 23 provides the control unit 24 with an instruction to change the combination of the beam groups to be used for drawing, based on information representing the position of a defective beam and an irradiation amount obtained using the defective beam. Accordingly, irradiation with electron beams could be performed with a target irradiation amount using the response state of the defective beam.

### Method for Manufacturing Article

A method for manufacturing an article (semiconductor integrated circuit device, liquid crystal display device, compact disc rewritable (CD-RW), mask for exposure device, or the like) according to an embodiment of the present invention includes a step of drawing a pattern on a substrate, such as a Si wafer or glass, using the above-described drawing apparatus, and a step of developing the substrate on which the pattern has been drawn. The method may further include other steps that are widely performed (oxidation, deposition, vapor deposition, doping, flattening, etching, resist removing, dicing, bonding, packaging, and so forth).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-247123, filed Nov. 29, 2013, which is hereby incorporated by reference herein in its entirety.

What is claimed is:

1. An apparatus that draws a pattern on a substrate using a plurality of beams, comprising:
a control unit configured to control the plurality of beams in units of a plurality of beam groups, a number of the plurality of beam groups being smaller than the number of the plurality of beams; and
an instruction unit configured to provide an instruction to the control unit,
wherein the instruction unit provides the instruction by adjusting a combination of beam groups to be used for drawing at a certain position on the substrate, based on information about a defective beam among the plurality of beams.

2. The apparatus according to claim 1, wherein the instruction unit adjusts a combination of beam groups to be used for drawing at the certain position on the substrate, based on an expected irradiation amount at the certain position and the information about the defective beam.

3. The apparatus according to claim 1, wherein the information about the defective beam represents a position of the defective beam and a response state of the defective beam for the instruction.

4. The apparatus according to claim 1, wherein one of the plurality of beam groups and another one of the plurality of beam groups have different numbers of beams.

5. The apparatus according to claim 1, wherein at least one of the plurality of beam groups is a beam group to which a single beam belongs.

6. The apparatus according to claim 1, wherein the control unit performs switching so that the defective beam belonging to one of the plurality of beam groups is moved to belong to another one of the plurality of beam groups.

7. The apparatus according to claim 6, wherein the another one beam group includes a larger number of beams than the one beam group.

8. The apparatus according to claim 1, wherein the control unit controls irradiation or non-irradiation of the plurality of beams, and the instruction unit provides the instruction so that an expected number of irradiations with the plurality of beams at the certain position is not changed.

9. A method for drawing a pattern on a substrate using a plurality of beams, comprising:
providing an instruction to control the plurality of beams in units of a plurality of beam groups, a number of the plurality of beam groups being smaller than the number of the plurality of beams; and
controlling the plurality of beams in response to the instruction,
wherein, in the providing, the instruction is provided by adjusting a combination of beam groups to be used for drawing at a certain position on the substrate, based on information about a defective beam among the plurality of beams.

10. The method according to claim 9, further comprising adjusting a combination of beam groups to be used for drawing at the certain position on the substrate, based on an expected irradiation amount at the certain position and the information about the defective beam.

11. The method according to claim 9, wherein the information about the defective beam represents a position of the defective beam and a response state of the defective beam for the instruction.

12. The method according to claim 9, wherein one of the plurality of beam groups and another one of the plurality of beam groups have different numbers of beams.

13. The method according to claim 9, wherein at least one of the plurality of beam groups is a beam group to which a single beam belongs.

14. The method according to claim 9, further comprising performing switching so that the defective beam belonging to one of the plurality of beam groups is moved to belong to another one of the plurality of beam groups.

15. The method according to claim 14, wherein the another one beam group includes a larger number of beams than the one beam group.

16. The method according to claim 9, further comprising:
controlling irradiation or non-irradiation of the plurality of beams; and
providing the instruction so that an expected number of irradiations with the plurality of beams at the certain position is not changed.

17. A method for manufacturing an article, comprising:
irradiating a substrate with a beam using an apparatus that draws a pattern on a substrate using a plurality of beams; and
developing the substrate,
wherein the irradiating includes:
controlling the plurality of beams in units of a plurality of beam groups, a number of the plurality of beam groups being smaller than the number of the plurality of beams, and
providing an instruction for the controlling by adjusting a combination of beam groups to be used for drawing at a certain position on the substrate, based on information about a defective beam among the plurality of beams.
